(19) United States
(12) Patent Application Publication
(10) Pub. No.: US 2008/0176399 A1
(43) Pub. Date: Jul. 24, 2008

(54) METALLIC SILICIDE FORMING METHOD AND METHOD OF MANUFACTURING SEMICONDUCTOR DEVICE

(76) Inventors: Takahiro Katagiri, Tokyo (JP); Yasunori Sogoh, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/671,589

(22) Filed: Feb. 6, 2007

(30) Foreign Application Priority Data
Feb. 8, 2006 (JP) P2006-031218

(51) Int. Cl. H01L 21/44

(52) U.S. Cl. 438/682; 257/E21.476

(57) ABSTRACT

A metallic silicide forms method of forming a metallic silicide layer on a semiconductor region containing silicon. The method includes the steps of: forming a first metal layer containing a first metal on the semiconductor region; forming a second metal layer containing a second metal on the semiconductor region to cover the first metal layer formed in the step of forming a first metal layer; and siliciding the semiconductor region with at least one of the first metal layer and the second metal layer by performing a heat treatment for the semiconductor region in which the second metal layer is formed to cover the first metal layer in the step of forming a second metal layer, forming the metallic silicide layer. The first metal layer is formed at a first temperature to be silicided. The second metal layer is formed at a second temperature lower than the first temperature.

### CROSS REFERENCE TO RELATED APPLICATIONS

The present invention contains subject matter related to Japanese Patent Application JP 2006-031218 filed in Japanese Patent Office on Feb. 8, 2006, the entire contents of which being incorporated herein by reference.

### BACKGROUND OF THE INVENTION

1. Field of the Invention

The present invention relates to a metallic silicide forming method and a method of manufacturing a semiconductor device, and more particularly to a metallic silicide forming method of forming a metallic silicide layer on a semiconductor region containing therein silicon and a method of manufacturing a semiconductor device.

2. Description of the Related Art

Shrink, high integration and the like are demanded for semiconductor devices. For this reason, for example, a channel region is shrunk in a metal oxide semiconductor (MOS) transistor. As a result, the transistor characteristics are deteriorated due to a short channel effect in some cases. In order to dissolve this nonconformity, in the MOS transistor, for example, shallow junctions are formed at a source region and a drain region, respectively, and a metallic silicide layer is formed in order to reduce contact resistances in the source and drain regions.

This metallic silicide layer, for example, is formed in a salicide (self-aligned silicide) process. The metallic silicide layer formed in the salicide process, for example, is disclosed in Japanese Patent Laid-open No. Hei 09-283465, Japanese Patent Laid-open No. Hei 07-273066, Japanese Patent Laid-open No. Hei 07-94449, and Japanese Patent Laid-open No. Hei 04-299825.

### SUMMARY OF THE INVENTION

More specifically, in the salicide process, firstly, a metal is deposited so as to correspond to a region in which a metallic silicide layer is intended to be formed in a semiconductor region containing therein silicon, thereby forming a metal layer. For example, nickel is deposited at a room temperature by utilizing a sputtering method so as to cover a gate electrode made of polysilicon, and a pair of source and drain regions which are formed on a silicon semiconductor substrate and between which the gate electrode is formed, thereby forming a metal layer.

Next, the silicon in the necessary semiconductor regions is silicided with the metal of the metal layer by performing a heat treatment, thereby forming a metallic silicide layer. For example, the silicon in the necessary semiconductor regions, and the metal layer made of nickel are made to react with each other in an ambient atmosphere of a high temperature of 250 to 400° C., thereby forming a nickel silicide (NiₓSi: X=1 to 2) layer.

Next, a portion of the metal layer which is left because no semiconductor region is silicided with it is removed. For example, the portion of the metal film which is left unreacted is removed by performing etching processing using a mixed liquid (mixed acid) of a sulfuric acid and a hydrogen peroxide.

Next, by performing the heat treatment again, the silicidization is made to progress, thereby growing the metallic silicide layer. For example, the heat treatment is performed again at a temperature of 450 to 650° C. higher than that in the heat treatment described above. As a result, the nickel silicide layer is grown so as to cover a surface of a gate electrode made of polysilicon and a surface of a pair of source and drain regions which is formed on a silicon semiconductor substrate and between which the gate electrode is formed.

In the way described above, the metallic silicide layer is formed in a self-alignment manner in the salicide process.

However, when the metallic silicide layer is formed in the manner as described above, it is difficult to control sizes of nuclei of the metallic silicide. As a result, the nuclei of the metallic silicide may be locally formed in large size. Hence, grain sizes may be formed in large size and thus the metallic silicide layer may not be uniform. That is to say, the metallic silicide may cohere and abnormally grow, so that the grain sizes become ununiform in some cases. More specifically, since the nuclei of nickel grow in large size during the deposition of nickel, when the heat treatment is then carried out, the metallic silicide layer, for example, is formed to have the grain sizes falling within the range of 50 to 500 nm. For this reason, a leakage may occur in an active region in which a MOS transistor is formed or a resistance of the active region may increase due to ununiformity of the grain sizes in the metallic silicide layer. Thus, the desired transistor characteristics may not be obtained in some cases.

As described above, the reliability of the semiconductor device is reduced due to the ununiformity of the grain sizes in the metallic silicide layer in some cases.

Accordingly, it is therefore desirable to provide a metallic silicide forming method which is capable of unifying grain sizes of a metallic silicide layer and of enhancing reliability and a method of manufacturing a semiconductor device.

According to an embodiment of the present invention, there is provided a metallic silicide forming method of forming a metallic silicide layer on a semiconductor region containing therein silicon, the method including the steps of: forming a first metal layer containing therein a first metal on the semiconductor region; forming a second metal layer containing therein a second metal on the semiconductor region so as to cover the first metal layer formed in the step of forming a first metal layer; and siliciding the semiconductor region with at least one of the first metal layer and the second metal layer by performing a heat treatment for the semiconductor region in which the second metal layer is formed so as to cover the first metal layer in the step of forming a second metal layer, thereby forming the metallic silicide layer, in which the first metal layer is formed at a first temperature at which the semiconductor region is allowed to be silicided with the first metal in the step of forming a first metallic layer, and the second metal layer is formed at a second temperature lower than the first temperature in the step of forming a second metal layer.

According to another embodiment of the present invention, there is provided a method of manufacturing a semiconductor device having a metallic silicide layer formed on a semiconductor region containing therein silicon, the method including the steps of: forming a first metal layer containing therein a first metal on the semiconductor region; forming a second metal layer containing therein a second metal on the semiconductor region so as to cover the first metal layer formed in the step of forming a first metal layer; and siliciding the semiconductor region with at least one of the first metal layer and the second metal layer by performing a heat treatment for the semiconductor region in which the second metal layer is formed so as to cover the first metal layer in the step of forming a second metal layer, thereby forming the metallic silicide layer, in which the first metal layer is formed at such a first temperature that the semiconductor region is allowed to be silicided with the first metal in the step of forming a first metallic layer, and the second metal layer is formed at a second temperature lower than the first temperature in the step of forming a second metal layer.

According to the present invention, first of all, the first metal is deposited on the semiconductor region at such a first temperature as to allow the semiconductor region containing therein silicon to be silicided with the first metal, thereby forming the first metal layer. Next, the second metal is deposited on the semiconductor region at the second temperature lower than the first temperature so as to cover the resulting first metal layer, thereby forming the second metal layer. Next, the semiconductor region is silicided with at least one of the first metal layer and the second metal layer by performing the heat treatment for the semiconductor region in which the second metal layer is formed so as to cover the first metal layer, thereby forming the metallic silicide layer.

According to the present invention, it is possible to provide the metallic silicide forming method which is capable of unifying grain sizes of the metallic silicide layer and of enhancing the reliability, and the method of manufacturing a semiconductor device.

### BRIEF DESCRIPTION OF THE DRAWINGS

FIG. 1 is a cross sectional view showing a main portion of a semiconductor device according to an embodiment of the present invention;

FIGS. 2A to 2C are respectively cross sectional views showing processes for manufacturing the semiconductor device according to the embodiment of the present invention; and

FIG. 3 is a cross sectional view showing a portion having a first metal layer formed therein on a semiconductor substrate having source and drain regions formed thereon in the semiconductor device according to the embodiment of the present invention.

### DETAILED DESCRIPTION OF THE PREFERRED EMBODIMENTS

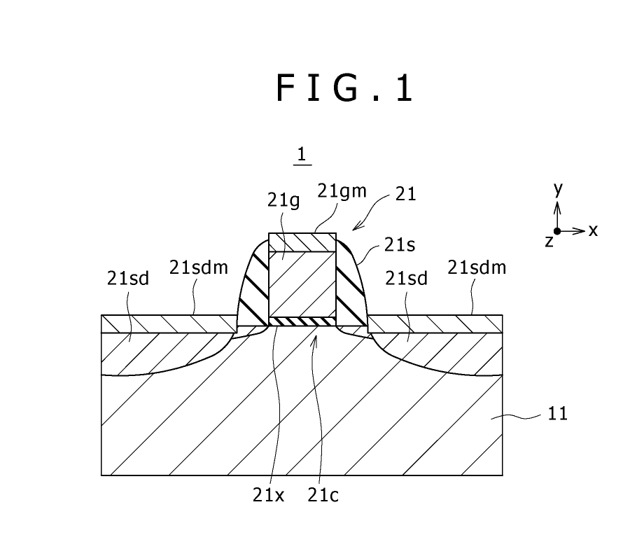

FIG. 1 is a cross sectional view showing a main portion of a semiconductor device according to an embodiment of the present invention.

As shown in FIG. 1, a semiconductor device 1 of this embodiment includes a semiconductor substrate 11 and a MOS transistor 21.

The semiconductor substrate 11 is made of, for example, single crystal silicon, and has a principal surface on which the MOS transistor 21 is formed.

The MOS transistor 21, as shown in FIG. 1, has a lightly doped drain (LDD) structure. The MOS transistor 21 is formed on the principal surface of the semiconductor substrate 11 so as to correspond to a region defined by an isolation layer (not shown).

Here, in the MOS transistor 21, a channel region 21c, as shown in FIG. 1, is formed on the principal surface of the semiconductor substrate 11.

Also, in the MOS transistor 21, a gate insulating film 21x, as shown in FIG. 1, is formed so as to correspond to the channel region 21c. The gate insulating film 21x, for example, is made of a silicon oxide to have a thickness of 0.1 to 5.0 nm.

In addition, in the MOS transistor 21, a gate electrode 21g, as shown in FIG. 1, is formed through lamination so as to correspond to the channel region 21c through the gate insulating film 21x. For example, the gate electrode 21g is formed from polysilicon so as to have a thickness of about 100 to about 200 nm. Also, a sidewall spacer 21s made of an insulator is formed on each of sidewall portions of the gate electrode 21g. In addition, in this embodiment, as shown in FIG. 1, a metallic silicide layer 21gm is formed on the gate electrode 21g on a side opposite to the gate insulating film 21x. For example, the metallic silicide layer 21gm is made of a nickel silicide.

Also, in the MOS transistor 21, a pair of source and drain regions 21sd is formed so as to hold the channel region 21c between the source and drain regions 21sd. The pair of source and drain regions 21sd has extension regions formed in regions which correspond to the sidewall spacers 21s, respectively, and between which the channel region 21c is formed. Also, impurity diffusion regions are formed so as to hold the channel region 21c between them through the respective extension regions. Here, each of the impurity diffusion regions has a higher impurity concentration than that of each of the extension regions and has an impurity diffusion depth deeper than that of each of the extension regions. For example, impurity ions are implanted into the principal surface of the semiconductor substrate 11 to be diffused into deeper portions, thereby forming the impurity diffusion regions in the pair of source and drain regions 21sd, respectively. Also, in this embodiment, each of metallic silicide layers 21sdm, as shown in FIG. 1, is formed on the surface of the pair of source and drain regions 21sd. For example, each of the metallic silicide layers 21sdm is formed from a nickel silicide.

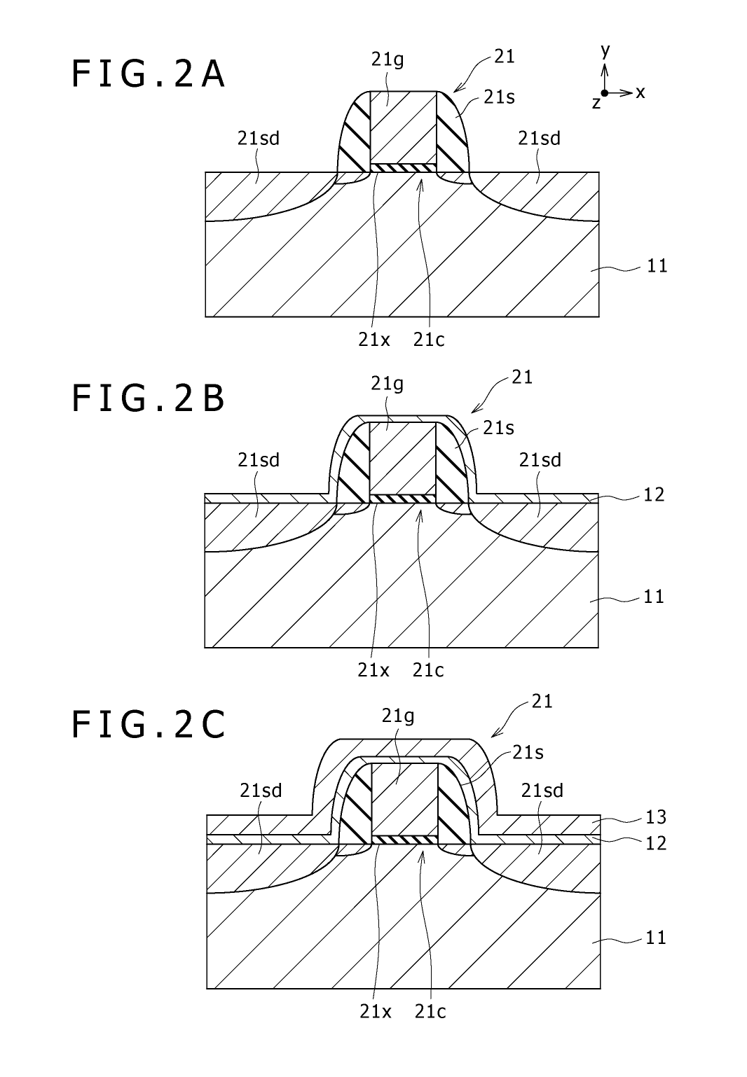

A method of manufacturing the semiconductor device according to this embodiment of the present invention will be described in detail hereinafter with reference to FIGS. 2A to 2C.

FIGS. 2A to 2C are respectively cross sectional views showing processes for manufacturing the semiconductor device according to this embodiment of the present invention. Here, the cross sectional views in the respective processes in the method of manufacturing the semiconductor device 1 are shown in order of FIGS. 2A, 2B and 2C.

When the semiconductor device 1 of this embodiment is intended to be manufactured, firstly, as shown in FIG. 2A, the MOS transistor 21 is formed.

In this case, as shown in FIG. 2A, the MOS transistor 21 is formed on the principal surface of the semiconductor substrate 11 made of single crystal silicon so as to have the LDD structure.

More specifically, firstly, the gate insulating film 21x of the MOS transistor 21 is formed.

In this case, the semiconductor substrate 11 is thermally oxidized to form the silicon oxide having a thickness of about 1 to about 5 nm on the surface of the semiconductor substrate 11. As a result, the gate insulating film 21x is formed so as to correspond to the channel region 21c.

Next, the gate electrode 21g of the MOS transistor 21 is formed.

In this case, for example, polysilicon is deposited to have a thickness of about 100 to 200 nm and so as to cover the gate insulating film 21x by utilizing a chemical vapor deposition (CVD) method, thereby forming a polysilicon film (not shown). Also, a mask layer (not shown) is formed on the resulting polysilicon film so as to correspond to the channel region 21c. After that, the polysilicon film is selectively etched away with the mask layer as an etching mask by utilizing a reactive ion etching (RIE) method, thereby obtaining the gate electrode 21g through the patterning processing as shown in FIG. 2A.

Next, a pair of source and drain regions 21sd is formed on the surface of the semiconductor substrate 11.

In this case, impurity ions are implanted into portions of the semiconductor substrate 11 located in both end portions of the gate electrode 21g, respectively, with the gate electrode 21g as a mask, thereby forming a pair of extension regions. After that, the sidewall spacer 21s is formed on each of the sidewalls of the gate electrode 21g. Also, impurity ions are implanted into portions of the semiconductor substrate 11 located in both end portions of the sidewall spacers 21s, respectively. Then, the impurity ions are activated by performing anneal processing. As a result, a pair of extension regions, and a pair of highly concentrated impurity diffusion regions are formed. In this case, each of the highly concentrated impurity diffusion regions has the higher impurity concentration than that of each of the extension regions, and has the deeper impurity diffusion depth than that of each of the extension regions. As a result, the source and drain regions 21sd having the extension regions and the highly concentrated impurity diffusion regions are formed in a pair.

Next, as shown in FIG. 2B, a first metal layer 12 is formed on the surface of the MOS transistor 21.

In this case, a first metal is deposited so as to cover the surface of the MOS transistor 21 at such a first transistor as to allow silicidization to occur in the pair of source and drain regions 21sd and the gate electrode 21g by utilizing a physical vapor deposition (PVD) method. As a result, the first metal layer 12 is formed on the surface of the MOS transistor 21.

More specifically, a pretreatment for removing a natural oxide film is carried out. After that, nickel is deposited as the first metal so as to cover the surface of the CMOS transistor 21 by utilizing the sputtering method in an ambient atmosphere of a gas containing at least one of N₂, He, Ne, Ar, Kr, Xe, Rn and H₂ at such a first temperature as to allow the silicidization to occur in the pair of source and drain regions 21sd, and the gate electrode 21g to form the nickel silicide. As a result, the first metal layer 12 is formed. In this embodiment, nickel is deposited so as to cover the surface of the CMOS transistor 21 within a closed container having the ambient atmosphere in which the first temperature is set in the range of 150 to 250° C. so as not to form NiSi₂ having a high resistance in the nickel silicide. Thus, a nickel film having a thickness of 0.2 to 3.0 nm is formed as the first metal layer 12 so that crystalline nuclei becoming nuclei are formed when the metallic silicide layers 21gm and 21sdm described above are formed.

Here, when the temperature during the deposition of the metal is lower than 150° C., the nonconformity may occur in which no nucleus of the nickel silicide is formed, the nuclei become uniform, and so forth. On the other hand, when the temperature during the deposition of the metal exceeds 250° C., the nonconformity may occur in which the nuclei of the nickel silicide grow, so that the grain sizes after completion of the heat treatment become large. In addition, when the thickness of the first metal layer 12 is smaller than 0.2 nm, the nonconformity may occur in which since the nuclei of the nickel silicide become sparse in formation, the grain sizes after completion of the heat treatment become large or uniform, and so fourth. On the other hand, when the thickness of the first metal layer 12 exceeds 3 nm, the nonconformity may occur in which the nickel silicide grows for a time period necessary for the deposition, so that the grain sizes become large.

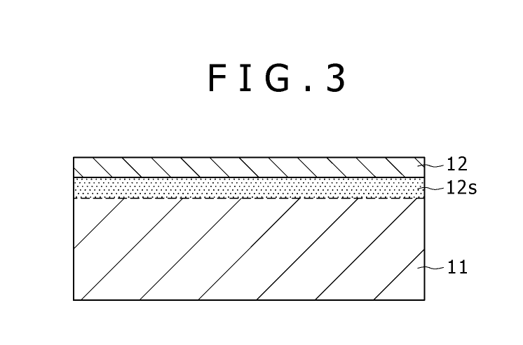

FIG. 3 is a cross sectional view showing a portion in which the first metal layer 12 is formed on the semiconductor substrate 11 having the source and drain regions 21sd formed therein in this embodiment of the present invention. It should be noted that this cross sectional view is also applied to a portion in which the first metal layer 12 is formed on the gate electrode 21g.

As shown in FIG. 3, in this process, nickel is deposited on the semiconductor substrate 11 at such a first temperature as to allow the silicidization to occur. Thus, a crystal layer 12s in which the crystalline nuclei containing therein the nickel silicide exist with high density is formed on the surface of the semiconductor substrate 11. In this case, the crystal layer 12s is formed so that the crystalline nuclei do not fuse each other and dispersively exist in small size.

Next, as shown in FIG. 2C, a second metal layer 13 is formed.

In this case, a second metal is deposited at a second temperature lower than the first temperature in the preceding process so as to cover the first metal layer 12 formed in the preceding process by utilizing the PVD method. As a result, the second metal layer 13 is formed. In this embodiment, the second metal is deposited at such a temperature, as to inhibit the silicidization from occurring in the semiconductor region, as the second temperature, thereby forming the second metal layer 13.

More specifically, nickel is deposited as the second metal by utilizing the sputtering method in an ambient atmosphere of a gas containing at least one of N₂, He, Ne, Ar, Kr, Xe, Rn and H₂ at such a second temperature as not to form the nickel silicide in the pair of source and drain regions 21sd and the gate electrode 21g. As a result, the second metal layer 13 is formed. In this embodiment, firstly, the semiconductor substrate 11 in this manufacturing stage is moved from the closed container which has the ambient atmosphere at the first temperature and in which the semiconductor substrate 11 has been accommodated in the preceding process to be accommodated in another closed container having an ambient atmosphere at a temperature which is set, as the second temperature, equal to or higher than the room temperature and lower than 150° C. After that, nickel is deposited on the surface of the MOS transistor 21 within the another closed container having the ambient atmosphere at the second temperature. As a result, for example, a nickel film having a thickness of 3 to 15 nm is formed as the second metal layer 13.

Next, as shown in FIG. 1, the metallic silicide layers 21gm and 21sdm are formed on the surfaces of the gate electrode 21g, and the source and drain regions 21sd, respectively.

In this case, the pair of source and drain regions 21sd and the gate electrode 21g are silicided with at least one of the first metal layer 12 and the second metal layer 13 by performing the heat treatment for the semiconductor substrate 11 in which the second metal layer 13 is formed so as to cover the first metal layer 12, thereby forming the metallic silicide layers 21sdm and 21gm, respectively.

That is to say, the silicidization of the semiconductor substrate 11 made of single crystal silicon, having the pair of source and drain regions 21sd formed thereon, with at least one of the first metal layer 12 and the second metal layer 13 is made to progress by growing the grains of the metallic silicide with the crystalline nuclei as the source formed when the first metal layer 12 is formed. As a result, each of the metallic silicide layers 21sdm is formed on the surfaces of the pair of source and drain regions 21sd. Also, concurrently with the progress of this process, the silicidization of the gate electrode 21g made of polysilicon with at least one of the first metal layer 12 and the second metal layer 13 is made to progress by growing the grains of the metallic silicide with the crystalline nuclei as the source formed when the first metal layer 12 is formed. As a result, the metallic silicide layer 21gm is formed on the surface of the gate electrode 21g.

More specifically, firstly, a first heat treatment is carried out for the semiconductor substrate 11 having the necessary portions formed thereon. For example, the first heat treatment is carried out so that the heat treatment time period of 10 to 120 seconds at the temperature set equal to or higher than 250° C. and lower than 450° C. is obtained in the ambient temperature of the gas containing at least one of N₂, He, Ne, Ar, Kr, Xe, Rn and H₂ by performing the lamp heating. Note that, in addition thereto, the first heat treatment may be carried out by using an electric furnace, a laser heating apparatus, a spike annealer or the like. For example, when the electric furnace is used, the first heat treatment is carried out for a processing time period of two minutes to an hour.

Then, portions of the first metal layer 12 and the second metal layer 13 which are left because neither of the surface of the gate electrode 21g, and the surfaces of the source and drain regions 21sd is silicided with it in the first heat treatment are removed by performing etching processing. For example, the portions of the first metal film 12 and the second metal film 13 which are left unreacted in the silicidization are etched away by utilizing a wet etching method using the mixed liquid (mixed acid) of a sulfuric acid and a hydrogen peroxide. Note that, in addition thereto, the portions of the first metal film 12 and the second metal film 13 which are left unreacted in the silicidization may be etched away by utilizing a dry etching method.

Next, a second heat treatment is carried out for the semiconductor substrate 11 from which both the first metal layer 12 and the second metal layer 13 have been removed. In this case, the second heat treatment is carried out at a higher temperature than that in the first heat treatment described above. For example, the second heat treatment is carried out so that a heat treatment time period of 4 to 120 seconds is obtained in an ambient atmosphere of a temperature of 450 to 600° C. through the lamp heating. Note that, in addition thereto, the second heat treatment may be carried out by using an electric furnace, a laser heating apparatus, a spike annealer or the like.

The semiconductor device 1 of this embodiment is manufactured in the manner described above. In this case, it is confirmed that the grain sizes of each of the metallic silicide layers 21gm and 21sdm in the semiconductor device 1 of this embodiment are in the range of 10 to 50 nm, and thus small and uniform.

As described above, in this embodiment, the first metal is deposited on the semiconductor region at the first temperature at which the silicidization is allowed to occur in the semiconductor region concerned, containing therein silicon, such as the semiconductor substrate 11, made of single crystal silicon, having the source and drain regions 21sd formed thereon, and the gate electrode 21g made of polysilicon. As a result, the first metal layer 12 containing therein the first metal is formed. Next, the second metal 13 is deposited on the semiconductor region concerned at the second temperature lower than the first temperature so as to cover the first metal layer 12 thus formed, thereby forming the second metal layer 13 containing therein the second metal. Next, the heat treatment is carried out for the semiconductor region concerned in which the second metal layer 13 is formed so as to cover the first metal layer 12, thereby siliciding the semiconductor region concerned containing therein silicon with at least of the first metal layer 12 and the second metal layer 13. As a result, the metallic silicide layers 21gm and 21sdm are formed. For this reason, in this embodiment, as described above, nickel is deposited on the semiconductor substrate 11 at such a high first temperature as to allow the silicidization to occur, thereby forming the first metal layer 12. Hence, the crystal layer 12s in which the crystalline nuclei containing the nickel silicide exist with high density is formed on the surface of the semiconductor substrate 11. Also, nickel is deposited at the lower second temperature than the first temperature so as to cover the first metal layer 12, thereby forming the second metal layer 13. Hence, the crystalline nuclei of the first metal layer 12 do not fuse each other and dispersively exist in small size. Also, the grains of the metallic silicide are grown with the crystalline nuclei as the source to be formed in the form of the metallic silicide layers 21gm and 21sdm by performing the heat treatment. As a result, the metallic silicide layers 21gm and 21sdm have the small and uniform grain sizes. Therefore, in this embodiment, the crystalline nuclei of the metallic silicide are not locally formed in large size. Hence, it is possible to prevent the leakage from occurring in the active region in which the MOS transistor is formed, and it is also possible to prevent the nonconformity such that the resistance becomes larger than is desired from occurring. Consequently, according to this embodiment, it is possible to unify the grain sizes in the metallic layers, and it is possible to enhance the reliability of the semiconductor device.

It should be noted that when being implemented, the present invention is not intended to be limited to the above-mentioned embodiment, and the various changes thereof can be adopted.

For example, although in the above-mentioned embodiment, the description has been given with respect to the case where each of the first metal layer and the second metal layer is formed by utilizing the sputtering method, the present invention is not limited thereto. For example, each of the first metal layer and the second metal layer may be formed by utilizing an electron beam evaporation method. In addition thereto, when the first metal layer is formed, metal ions allowing the silicidization to occur may be implanted into the semiconductor region containing therein silicon. In this case, for example, nickel ions are implanted into the semiconductor region containing therein silicon at an acceleration voltage of 10 keV with a dosage of 1×10¹⁵ cm⁻² in the same temperature ambient atmosphere as that in the above-mentioned embodiment, thereby forming the first metal layer containing therein nickel as the first metal.

In addition, although in the above-mentioned embodiment, the description has been given with respect to the case where the metallic silicide layer made of the nickel silicide is formed, the present invention is not intended to be limited thereto. For example, the present invention can also be applied to the case where the metallic silicide layer is formed which is obtained by siliciding the semiconductor region with a metal such as titanium, cobalt, platinum or palladium, or any of alloys of various metals. More specifically, when the semiconductor region is intended to be silicided with titanium or cobalt, the silicidization is preferably carried out under the condition of the deposition temperature of 350 to 500° C. and the condition of the heat treatment temperature of 500 to 850° C. when the above-mentioned first metal film is formed. In addition, in the case of platinum or palladium, the silicidization is preferably carried out under the condition of the deposition temperature of 250 to 400° C. and the condition of the heat treatment temperature of 400 to 850° C. when the above-mentioned first metal film is formed. Also, in the case of any of the alloys of the various metals, the condition set between both the conditions described above may be adopted.

In addition, although in the above-mentioned embodiment, the description has been given with respect to the case where the MOS transistor is formed as a semiconductor element in the semiconductor device, the present invention is not intended to be limited thereto. For example, the present invention can also be applied to the case where another semiconductor element such as a bipolar transistor is formed.

It should be understood by those skilled in the art that various modifications, combinations, sub-combinations and alterations may occur depending on design requirements and other factors insofar as they are within the scope of the appended claims or the equivalents thereof.

What is claimed is:

1. A metallic silicide forming method of forming a metallic silicide layer on a semiconductor region containing silicon, said method comprising the steps of:
forming a first metal layer containing a first metal on said semiconductor region;
forming a second metal layer containing a second metal on said semiconductor region so as to cover said first metal layer formed in said step of forming a first metal layer; and
siliciding said semiconductor region with at least one of said first metal layer and said second metal layer by performing a heat treatment for said semiconductor region in which said second metal layer is formed so as to cover said first metal layer in said step of forming a second metal layer, forming said metallic silicide layer,
wherein said first metal layer is formed at a first temperature at which said semiconductor region is allowed to be silicided with said first metal in said step of forming a first metallic layer, and
said second metal layer is formed at a second temperature lower than said first temperature in said step of forming a second metal layer.

2. The metallic silicide forming method according to claim 1, wherein the second temperature is a temperature inhibiting said semiconductor region from being silicided with said second metal.

3. The metallic silicide forming method according to claim 2, further comprising the steps of:
removing portions of said first metal layer and said second metal layer which are left because said semiconductor region is not silicided with said portion in said silicidization step from said semiconductor region by performing etching processing; and
carrying out a heat treatment for said semiconductor region from which said first metal layer and said second metal layer are removed in said removal step,
wherein in said heat treatment step, the heat treatment is carried out at a higher temperature than that in the heat treatment in said silicidization step.

4. A method of manufacturing a semiconductor device having a metallic silicide layer formed on a semiconductor region containing silicon, said method comprising the steps of:
forming a first metal layer containing a first metal on said semiconductor region;
forming a second metal layer containing a second metal on said semiconductor region so as to cover said first metal layer formed in said step of forming a first metal layer; and
siliciding said semiconductor region with at least one of said first metal layer and said second metal layer by performing a heat treatment for said semiconductor region in which said second metal layer is formed so as to cover said first metal layer in said step of forming a second metal layer, forming said metallic silicide layer,
wherein which said first metal layer is formed at such a first temperature that said semiconductor region is allowed to be silicided with said first metal in said step of forming a first metallic layer, and
said second metal layer is formed at a second temperature lower than the first temperature in said step of forming a second metal layer.
